(19) United States
(12) Patent Application Publication
(10) Pub. No.: US 2026/0271223 A1
(43) Pub. Date: Sep. 10, 2026

(54) Computer Component Cooling Systems

(71) Applicant: AGT-USA, Inc., Corona, CA (US)

(72) Inventor: Steven J. Barberi, Corona, CA (US)

(73) Assignee: AGT-USA, Inc., Corona, CA (US)

(21) Appl. No.: 19/551,485

(22) Filed: Feb. 26, 2026

Related U.S. Application Data
(63) Continuation-in-part of application No. 19/308,617, filed on Aug. 25, 2025, now Pat. No. 12,575,069.
(60) Provisional application No. 63/766,515, filed on Mar. 4, 2025.

(51) Int. Cl. H05K 7/20

(52) U.S. Cl. CPC H05K 7/202; H05K 7/20145; H05K 7/20236; H05K 7/20254; H05K 7/20263; H05K 7/20272; H05K 7/203; H05K 7/20436; H05K 7/20727; H05K 7/20772; H05K 7/20809; H05K 7/20836

(57) ABSTRACT

Systems for cooling computer systems in housings. The housing are made up of several panels making up the housing and thee panels have coolant channels within the panel walls. A first coolant is disposed within the housing, in direct contact with heat generating computer components. A second coolant is circulated through the channels, removing heat form the first coolant. The second coolant is passed to a heat exchanger, and is cooled by a third coolant (building chilled water, for example).

This application is a continuation-in-part of U.S. application Ser. No. 19/308,617, filed Aug. 25, 2025, pending, which claims priority to U.S. Provisional Application 63/766,515, filed Mar. 4, 2025, pending.

### FIELD OF THE INVENTIONS

The inventions described below relate to the computer component cooling systems.

### BACKGROUND

Computer systems used for server farms, high-performance servers and AI GPU's require cooling systems to remove heat generated by computer components housed within enclosures, to maintain the temperatures of the components within acceptable ranges. Currently, systems use air cooling, immersion cooling, and direct-to-chip cooling. Coolant is supplied through coolant distribution systems which include pumps and heat exchangers, and rely on a central cooling system (a building HVAC system, for example, cooling facility water). As these computing systems become more powerful, more cooling power is needed. Currently installed computer systems, with increasing heat loads, cannot be effectively cooled with currently installed coolant distribution systems, and would benefit from improved cooling capacity within rack-mounted housings. New systems can also benefit from improved cooling of the enclosures.

### SUMMARY

The systems and methods described below provide for enhanced cooling of computer systems, using new coolant flow paths within the walls of the computer enclosures. The system includes a rack-mountable computer system with a housing, comprising several panels making up the housing. The panels have coolant channels within the panel walls. A first coolant is disposed within the housing, in direct contact with heat-generating computer components. A second coolant is circulated through the channels, removing heat from the first coolant. The second coolant is passed to a heat exchanger, and is cooled by a third coolant (building chilled water, for example). This system can be installed in current systems by replacing one or more panels of installed rack-mounted server housings or in new installations.

### BRIEF DESCRIPTION OF THE DRAWINGS

FIG. 1 is a perspective view of a liquid immersion computer cooling system.

FIGS. 2 and 3 are cross-sections of the liquid immersion computer cooling system of FIG. 1, illustrating two-phase and single-phase operation of the system.

FIGS. 4 and 5 illustrate a cooling system using the housing of FIG. 1, in which coolant flow paths are configured for direct-to-chip cooling.

FIG. 6 illustrates a cooling system using the housing of FIG. 2, illustrating use of a spray system for enhanced cooling of components.

FIG. 7 illustrates a cooling system using the housing of FIG. 1, illustrating flow-through air cooling as a primary coolant combined with cooling provided through a secondary coolant passing through channels in a panel.

FIG. 8 illustrates a cooling system similar to that of FIGS. 1 and 4, with the direct-to-chip cooling similar to FIG. 4 and cooling through side panels as in FIG. 1

### DETAILED DESCRIPTION OF THE INVENTIONS

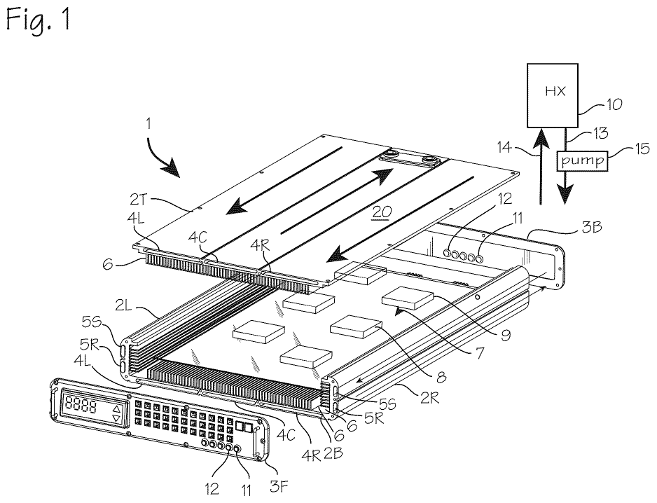

FIG. 1 is a perspective view of a liquid immersion computer cooling system. This figure shows a rack-mountable computer system 1 with a housing 2 which includes housing top and bottom panels 2T and 2B, and housing side panels 2R and 2L, and end panels (front and back panels) 3F and 3B. The top and bottom panels of the housing panels are thick enough to include channels 4 (the several channels marked 4L, 4C, 4R) which are configured to accommodate the flow of coolant through the panels. The left and right side panels 2R and 2L of the housing may also be thick enough to include side channels 5 (the several channels marked 5S for supply of coolant, 5R for return of coolant)which are configured to accommodate the flow of coolant through the side panels. Cooling fin assemblies 6 are fixed to and in thermal contact with the inner surface of at least one of the panels, and, in this embodiment, cooling fins are fixed to the top panels, the bottom panels or the side panels (all three panels, or any subset of the panels). Cooling pins may be used in place of the cooling fins. The housing is typically a cuboid (rectangular box) in commercial embodiments of rack-mountable computer housings, but may be any shape with corresponding panels of suitable geometry.

This housing provides a housing for a circuit board 7 and several computer components 8. These computer components generate heat and must be cooled to keep the temperature within the housing within the operating limits of the computer components. The circuit board 7 may include a number of computer components that are heat-generating components 9, which may include CPU's, graphics processors, memory or other components.

The housing 2, when assembled, is a sealed enclosure which establishes a sealed space which may be filled (partially or completely) with a primary coolant. The channels 4 and 5 in the top and bottom panels and left and right panels accommodate the flow of a secondary coolant. At least one, and preferably each of the top, bottom, right and left housing panels includes a supply coolant channel (one of 4, 5) and return coolant channel (a different one of 4, 5), for supply and return of a secondary coolant to and from the coolant channels, wherein each channel is disposed between an exterior wall of the panel and an interior wall of the panel, each supply coolant channel communicates at a first end thereof with a coolant supply line and each return coolant channel communicates at a first end thereof with a coolant supply line, and each supply coolant channel at a second end thereof with a return coolant channel at a second end thereof. As illustrated, coolant is supplied to the supply channels through supply port 11, passes forward through the supply channels 5S and returned through the return channels 5R and then through the return port 12 to the heat exchanger 10.

One of the panels (the back panel, front panel, or both) includes connecting ports for establishing fluid communication between the channels in the housing walls and an external heat exchanger/chiller 10. At least one supply port 11 and one return port 12 are provided, with the supply port in fluid communication with some channels, and the return port in fluid communication with other channels (or the opposite end of the same channels), for delivery of the secondary coolant to and from the housing through a supply line 13 and return line 14. A pump 15 is provided, disposed in the system and operable to pump coolant through the channel and the heat exchanger. These components, together with the side channels, establish a cooling loop for flow into and out of the channels. Flow through the channels enters and exits the same end panel, or with a supply port in one end panel and a return port in the other end panel if flow passes only in the first end panel and out the second end panel. Depending on where the heat-generating components are located with the housing, cold incoming secondary coolant may be ported to some channels, flow through the channels, and then returned as warmed secondary coolant through other channels. Any permutation may be used. For example, if the heat-generating components are located toward the sides of the enclosure, cold incoming secondary coolant may be ported through supply port 11 to channels 4L and 4R, and returned through channel 4C and thereafter ported through return port 12 to the external heat exchanger/chiller 10.

Though exemplified with channels in the side walls of the enclosure, an alternative inventive concept can be implemented with tubes close to the inner surface of the top, bottom, left and/or right panels. In all the illustrated systems, the outer surfaces 20 of one or more of the panels may be devoid of cooling fins, to limit heat transfer to the ambient environment and thus reduce the ambient air conditioning requirements.

### Immersion Cooling Two-Phase

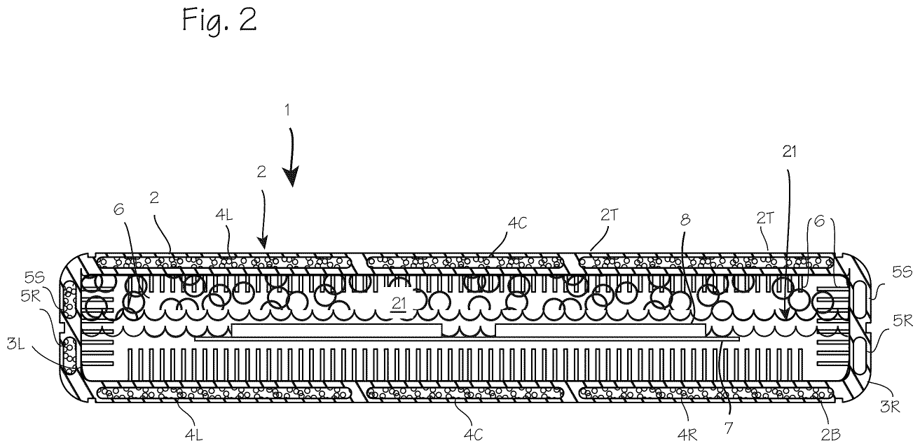

FIG. 2 shows a cross-section of the liquid immersion computer cooling system of FIG. 1 when operated as a two-phase cooling system. This figure shows the housing 2 in cross-section, with the circuit board 7 and heat-generating computer components 8 disposed within the housing, along with a primary coolant which covers, or partially covers, the heat-generating components. In operation, the channels 4L, R and C of the top panel 2T, and, optionally, the comparable channels 4L, R and C of the bottom panel 2B are filled with secondary coolant, flowing into some channels through one or more supply ports 11, through those channels, and out of the remaining channels through return ports 12. The flow may be directed through a supply port in the rear panel 3B, forward through one or more channels, and then retrograde through other channels (as in, supply through channels 4L, 4R and return through channel 4C (or vice versa) and out through a return port in the rear panel 3B, or through a supply port in the rear panel 3B forward through channels in the top panel and return through channels in the bottom panels and out through a return port in the rear panel 3B (or vice versa)). Flow may also be provided in a single-pass fashion, entering through supply ports in one of the end panels and exiting through a return port in the opposite end panel. The interior space of the housing is partially filled with a reservoir of coolant liquid which boils at temperatures achieved by the heating generating components. This is shown in FIG. 2 as the pool of liquid coolant 21. The coolant liquid is preferably deep enough to cover the heat-generating components. With an appropriately chosen coolant, heat generated by the components will cause the coolant to boil, with gaseous coolant rising within the housing. The resultant gaseous coolant is depicted in FIG. 2 as item 22. Secondary coolant flow in the channels in the top panel 2T cools the cooling fins, which in turn cool the gaseous primary cooling and cause the primary cooling to condense and fall to the bottom of the housing. Continued operation of the system results in a continuous cycle of evaporation of liquid coolant in the bottom of the chamber and condensation of the evaporated coolant at the top of the chamber, with heat being removed from the components by evaporation of the primary coolant and heat being removed from the primary coolant by the cold fins and secondary coolant. Secondary coolant may also be supplied through all the other channels, in the bottom panel and side panel, to cool the liquid phase of the primary coolant. Depending on the heat loads, cooling power of the primary and secondary coolants, the channels in the bottom panel and side channels may be omitted, or not used. This system may be built and operated without fans or pumps to circulate the primary coolant within the enclosure, and may rely on natural circulation of the primary coolant, though fans or pumps may be provided to aid in convective heat transfer from the components to the coolant liquid.

In this two-phase immersion configuration, the primary coolant, which is the coolant that first removes heat from the circuit board and heat-generating components, may be a non-conductive fluid (which need not be dielectric), a dielectric fluid, with a low boiling point (below the expected operating temperature of the enclosure), such as Perfluorotri-N-Butylamine (CAS No. 86508-42-1, boiling point 97° C., 207° F.) or Novec 7000 (Heptafluoro-1-Methoxypropane, CAS No. 375-03-1, boiling point 34 C., (93° F.). The secondary coolant, which is the coolant that removes heat from the primary coolant and transfers that heat to an external heat exchanger, and runs through the channels in the housing walls, may be water, glycol, or a mix of water and glycol, or other suitable coolant.

### Immersion Cooling Single-Phase

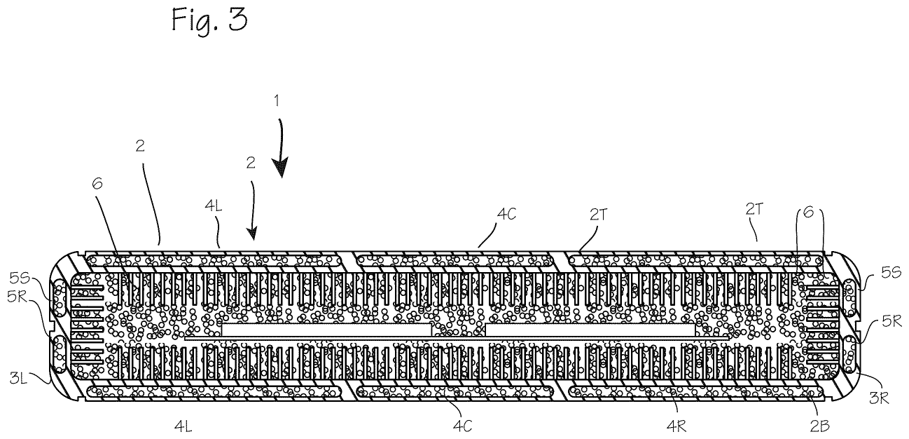

FIG. 3 shows a cross-section of the liquid immersion computer cooling system of FIG. 1 when operated as a single-phase cooling system. The housing, panels, channels and ports are the same as those mentioned in the discussion of FIGS. 1 and 2. This figure shows the housing 2 in cross-section, with the circuit board 7 and heat-generating computer components 8 disposed within the housing, along with a primary coolant which fills the enclosure and partially or entirely immerses the heat-generating components (some voids are permissible). The primary coolant is shown in FIG. 3 as item 23. With an appropriately chosen primary coolant (together with an appropriately chosen secondary coolant), heat generated by the components will not cause coolant to boil, though the primary coolant may rise and fall within the housing depending on the cooling provided by the various channels, to provide convective cooling of the heat-generating components.

Secondary coolant flow in the channels in the panels (so many of them that are used for cooling flow) cools the cooling fins, which in turn cool the liquid primary coolant. Continued operation of the system results in a continuous transfer of heat from the heat-generating components to the primary coolant, and heat being removed from the primary coolant by the cold fins and secondary coolant. Secondary coolant may also be supplied through all of the channels, in the top panel, the bottom panel and side panels. Depending on the heat loads, cooling power of the primary and secondary coolants, some channels depicted in the figure may be omitted, or not used. This system may be built and operated without fans or pumps (either within the housing or external to the housing) to circulate the primary coolant within the enclosure, and may rely on natural circulation of the primary coolant within the housing, convection or conduction of heat from the heat-generating components to the primary coolant and thence to the fins, though fans or pumps may be provided to aid in convective heat transfer from the components to the primary coolant liquid.

In this single-phase immersion configuration, the primary coolant, which is the coolant that first removes heat from the circuit board and heat-generating components, may be a non-conductive fluid (which need not be dielectric), a dielectric fluid, such as mineral oil, white oil, silicone oil, synthetic polyalphaolefins, with a boiling point above the expected operating temperature within the enclosure. The primary coolant fills the enclosure sufficiently to cover the heat-generating components. The secondary coolant, which is the coolant that removes heat from the primary coolant and transfers that heat to an external heat exchanger, and runs through the channels in the housing walls, may be water, glycol, or a mix of water and glycol, or other suitable coolant.

### Direct-to-Chip Cooling

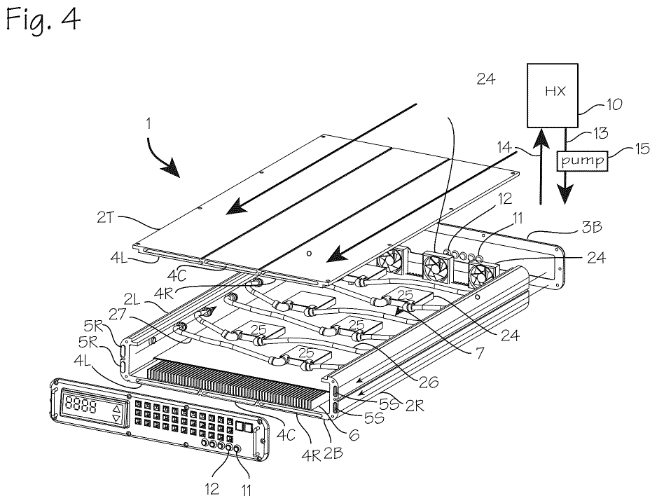

FIG. 4 is a perspective view of a direct-to-chip computer cooling system. This figure shows a rack-mountable computer system 1 with a housing 2 which includes housing top and bottom panels 2T and 2B, and housing side panels 2R and 2L, and end panels (front and back panels) 3F and 3B. The top and bottom panels of the housing panels are thick enough to include channels 4 which are configured to accommodate the flow of coolant through the panels. The left and right side panels 2R and 2L of the housing may also be thick enough to include channels 5S and 5R which are configured to accommodate the flow of coolant through the panels. Cooling fin assemblies 6 are fixed to and in thermal contact with the inner surface of at least one of the panels, and, in this embodiment, cooling fins are fixed to each of the top and bottom panels and the side panels. Fans 24 are disposed within the housing, for circulating a coolant within the housing. In FIG. 4, the coolant channels 5S in panel 2R are both used for supply of coolant, and coolant channels 5R in panel 2L are both used as return channels, with supply and return ports located in the back end panel 3B. Also, the channels 4L, 4C, 4R within top and bottom panels are, in this illustration, used for single-pass coolant flow, with coolant entering in one end, through the ports in the back end panel 3B, and exiting through ports in the front end panel 3F. The assignment of channels to inflow or outflow may be adjusted to accommodate varying heat loads on the circuit board 7.

As with FIG. 1, the housing provides a housing for a circuit board 7 and several computer components 8, at least some of which are heat-generating components 9.

This cooling system is configured for direct-to-chip cooling, and includes cooling jackets or cold plates 25 (cooling modules) over at least one of the heat-generating components 9. Direct-to-chip coolant is supplied from an external source, through a port in an end panel, through a channel in a housing panel, through direct-to-chip coolant supply lines 26, and into the jacket(s) 25 and returned through the direct-to-chip coolant return lines 27, then into different channels in the housing panel, out through return ports in an end panel, and then back to the external source (with a heat exchanger and pump interposed). In this figure, channels 5S in one side panel are used to supply coolant to the jacket 25 and channels 5R are used to return coolant from the jacket to the external heat exchanger. In addition, an additional coolant may be disposed within the housing, covering the circuit board and jacket.

The coolant supplied to the jackets through some channels and returned through other channels removes heat from the hottest heat-generating components. The cooling within the remainder of the housing removes heat both from the jackets and also from uncovered heat-generating components. Other channels may be used for additional cooling with external cooling, or not used at all, or not provided. For example, a first coolant can be delivered through side channels to the jackets and back to an external heat exchanger; a second coolant, resident within the housing, can be blown by the fans over the components and returned to fan intakes through the top and bottom center channels, and a third coolant can be supplied and returned through the left and right channels in the top and bottom panels. So, in the embodiment in which all three coolant modes are used, the direct-to-chip coolant constitutes a primary coolant supplied from an external source, the coolant resident in the housing constitutes a secondary coolant, and the coolant in the remaining channels not used for the primary coolant constitutes a tertiary coolant. Note that all of the channels may be used by the primary and tertiary coolant, and the secondary coolant may, instead of returning to the fan intakes through channels in the housing, may return to the fan intakes by passing retrograde between one surface 28 of the circuit board and one of the upper and lower panels, after passing prograde over the other surface 29 of the circuit board, it the secondary coolant can just be turbulently mixed within the housing, with no clearly defined flow path.

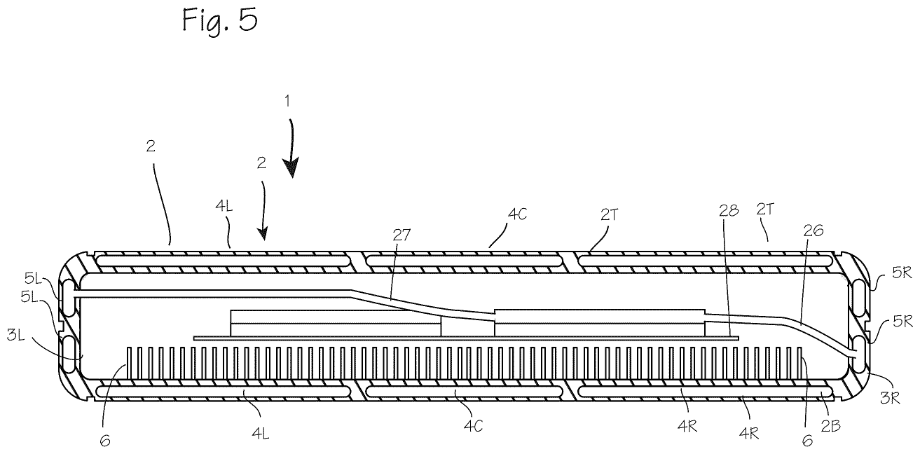

FIG. 5 shows a cross-section of the direct-to-chip cooling computer cooling system of FIG. 4. This figure shows the housing 2 in cross-section, with the circuit board 7 and heat-generating computer components 8 disposed within the housing and covered by the jackets 25. In operation, channels (for example, channels 5L and 5R in the side panels) may be used to supply primary coolant to the jackets and return primary coolant from the jackets to the external source, while the fans cause circulation of the secondary coolant over a surface of the circuit board (for return over the other surface of the circuit board or through channels in the housing), while other channels are used for flow of a tertiary coolant (in which case house coolant used to cool the heat exchanger 10 would be a fourth coolant). FIGS. 4 and 5 depict cooling fins only on the inside of the bottom panel, but cooling fins may be provided on the inside surfaces of other panels.

In this direct-to-chip configuration, the primary coolant, which is the coolant that first removes heat from the circuit board and heat-generating components, may be a non-conductive fluid (which need not be dielectric), a dielectric fluid, such as mineral oil, white oil, silicone oil, synthetic poly alpha olefins, with a boiling point above the expected operating temperature within the jackets. The primary coolant flows through the jackets and covers the heat-generating components.

The secondary coolant may also be a non-conductive fluid (which need not be dielectric, for example propylene glycol, ethylene glycol, calcium chloride solution, potassium formate/acetate), a dielectric fluid, such as mineral oil, white oil, silicone oil, synthetic poly alpha olefins, with a boiling point above the expected operating temperature within the jackets.

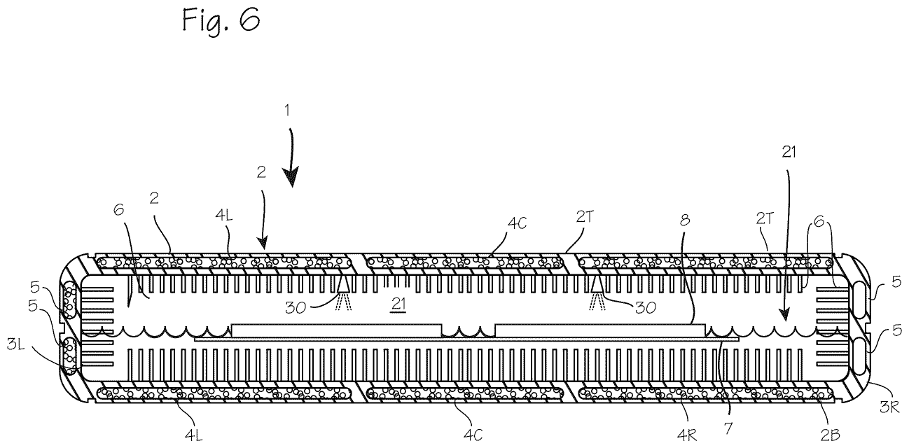

FIG. 6 illustrates a cooling system using the housing of FIG. 2, illustrating use of a spray system for enhanced cooling of components. As in FIG. 2, FIG. 6 includes the housing 2 in cross-section, with the circuit board 7 and heat-generating computer components 8 disposed within the housing, along with a primary coolant which covers, or partially covers, the heat-generating components. In operation, the channels 4L, R and C of the top panel 2T, and, optionally, the comparable channels 4L, R and C of the bottom panel 2B are filled with secondary coolant, flowing into some channels through one or more supply ports 11, through those channels, and out of the remaining channels through return ports 12. In addition, this system includes spray heads 30 disposed over or proximate heat-generating components 8. The coolant can be directed specifically toward heat-generating components within the housing through the spray heads disposed proximate the heat-generating components. The spray heads may be supplied with coolant from the pool of coolant 21 in the housing, driven by a pump 31 operable to draw coolant from the reservoir 21 of primary coolant. The pump 31 may be disposed within the housing or outside the housing. As illustrated, the pump feeds the spray heads through a supply line 32 and draws coolant from the coolant pool 21 through suction line 33. The pump may instead be located outside the housing, with the supply line and suction line penetrating the housing, preferably through one of the end panels.

In the description above, the term primary coolant is used to refer to coolant within the housing and the enclosure established by the panels, as it is the coolant that contacts the heat loads. The term secondary coolant is used to refer to coolant flowing through the channels and external heat exchanger. The external heat exchanger may be cooled with a third coolant loop (house cooling) with a tertiary coolant.

Referring to FIGS. 1, 2 and 3, a tertiary coolant, which is the coolant that removes heat from the secondary coolant passing through the heat exchanger 10 and transfers that heat to an external heat exchanger, may be water, glycol, or a mix of water and glycol, or other suitable coolant.

Existing computer component housings may be retrofitted with panels with coolant channels, without replacing all panels of a cuboid enclosure. For example, a panel of a pre-existing enclosure may be removed and replaced with a panel (most conveniently, top panel 2T with channels such as channels 4) in any of the figures, and these channels can be used, along with the heat exchanger 10, to remove heat from any coolant in an existing single-phase or two-phase cooling system that includes solid (without channels) panels in the remainder of the housing.

### Flow-Through Cooling

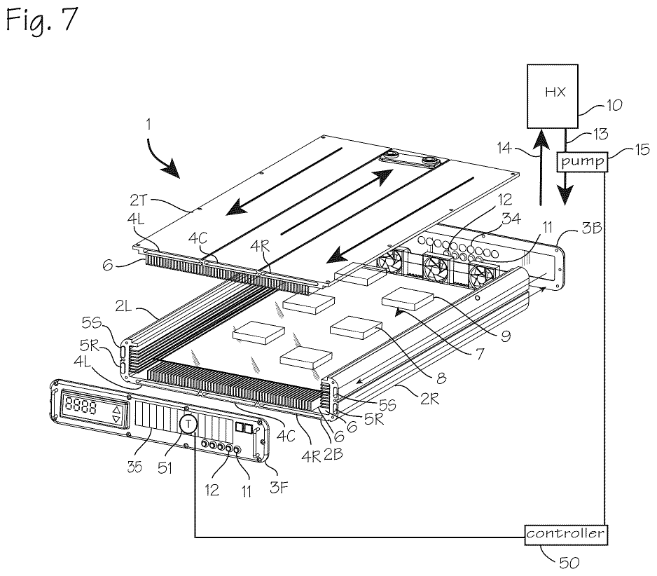

FIG. 7 illustrates a cooling system using the housing of FIG. 1, in which air passing through the housing is a primary coolant and fluid passing through channels in a panel acts as a secondary coolant. As with previous figures, this figure shows a rack-mountable computer system 1 with a housing 2 which includes housing top and bottom panels 2T and 2B, and housing side panels 2R and 2L, and end panels (front and back panels) 3F and 3B, containing several computer components 8, at least some of which are heat-generating components 9. The top and bottom panels of the housing panels are thick enough to include channels 4 which are configured to accommodate the flow of coolant through the panels. The left and right side panels 2R and 2L of the housing may also be thick enough to include channels 5S and 5R which are configured to accommodate the flow of coolant through the panels. Cooling fin assemblies 6 are fixed to and in thermal contact with the inner surface of at least one of the panels, and, in this embodiment, cooling fins are fixed to each of the top and bottom panels and the side panels. The heat exchanger (10) is in fluid communication with the coolant channels, through the supply line (13) and return line (14), establishing a coolant loop (4 or 5, 13, 14) for flow of a secondary coolant through the coolant channels (4, 5) which removes heat from the air in the enclosure and a pump (15) operable to pump coolant through the coolant loop (4, 5, 13, 14) and heat exchanger.

One or more fans 24 are disposed within the housing, in this embodiment for driving a primary coolant through the housing. The fan(s) are disposed in fluid communication with the apertures and the interior space of the housing, configured to draw air into the housing through the intake aperture and exhaust air through the outlet aperture. In FIG. 7, the coolant channels 5S in panel 2R and coolant channels 5R in panel 2L and the channels 4L, 4C, 4R within top or bottom panels may be used as described in relation to FIG. 4, or some may be omitted so long as at least panel with coolant channels is used. The system of FIG. 7 includes coolant gas intake apertures 34 in any one of the panels and gas outlet apertures 35 in any one of the panels (they are illustrated in front and back panels 3B, 3F, but could both be disposed in a top, bottom, or side panel). Ambient air is the most convenient coolant gas, and in this configuration is used as the primary coolant.

If the system of FIG. 7 is assembled as a retrofit of an existing housing, already provided with blowers and intake and outlet apertures, one of the top, bottom, left or side panels (preferably the top panel) of the existing housing may be removed and replaced with a panel provided with coolant channels and another pre-existing (preferably an end channel (front or back) can be replaced with a panel which includes coolant gas apertures and the secondary coolant ports 11 and 12. For ease of retrofitting, both the inlet and outlet apertures can be located on a replacement back-end panel 3B, and the replacement coolant panel and replacement end panel can be provided in a single assembly, with the panels securely fixed to each other, and configured to fit into pre-existing fittings in the pre-existing housing. This option is particularly convenient for modification of computer housings already installed in server racks.

The fans are, in this illustration, used for single-pass coolant flow, with coolant entering in one end, through the ports in the back end panel 3B, and exiting through ports in the front end panel 3F. The assignment of channels to inflow or outflow may be adjusted to accommodate varying heat loads on the circuit board 7. The fans and secondary coolant pump are operated in coordination with each other, controlled by a control system, to provide sufficient cooling gas to maintain heat generating components at a desired temperature and also provide secondary coolant flow at a temperature and flow rate sufficient to remove heat from the cooling gas and thereby cool the cooling gas exiting the housing. Preferably, the coolant flows are balanced so the temperature of the cooling gas exiting the enclosure does not deviate significantly from the temperature of the cooling gas entering the enclosure, which may include controlling the coolant flows to maintain the temperature of cooling gas exiting the enclosure below a threshold temperature.

The method of cooling computer components using this flow-through system entails implementation of the system, placing the heat generating computer components within the housing, operating the fan to force cooling gas through the housing to cool the computer components within the housing while operating the pump to force a coolant fluid through the coolant channel of one or more of the panels and controlling the fan and pump to balance flow of cooling gas through the housing and flow of coolant fluid through the channel of the panel to cool the cooling gas exhausted from the housing. Control may be accomplished with a computerized control system 50 which is interoperable with a sensor 51 operable to sense temperature of cooling gas passing through and exiting the housing, and operable to control the pump and/or associated throttle valves and/or control the fan or associated dampers or vents, or control may be accomplished by manually adjusting these components or providing components in manufacture with specifications suitable for balancing flow such that operation results in a desirable exhaust temperature.

### Direct to Chip with Endplate Manifold

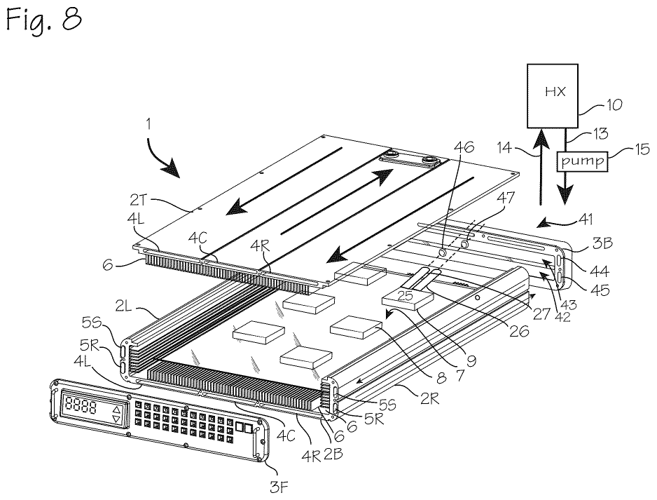

FIG. 8 illustrates a cooling system similar to that of FIGS. 1 and 4, with the direct-to-chip cooling similar to FIG. 4 and cooling through at least one of the panels as in FIG. 1. The cooling system of FIG. 8 includes the computer system 1, housing 2 with top and bottom panels 2T and 2B and housing side panels 2R and 2L, and end panels (front and back panels) 3F and 3B, cooling fin assemblies 6, fans 24 as described in FIG. 1. As with FIG. 1, the housing provides a housing for a circuit board 7 and several computer components 8, at least some of which are heat-generating components 9.

This cooling system is configured for direct-to-chip cooling, and includes a liquid cooling module such as cooling jackets or cold plates 25 over at least one of the heat-generating components 9. Direct-to-chip coolant is supplied from an external source, through a port in an end panel (directly from the end panel, without porting to a side channel as in FIG. 4) through direct-to-chip coolant supply lines 26, and into the jacket(s) 25 and returned through the direct-to-chip coolant return lines 27, then out through return ports in an end panel, and then back to the external source (with a heat exchanger and pump interposed). In this figure, channels 5S and 5R may be used to supply coolant to other cooling jackets, cool a primary coolant within the housing, or they may be omitted altogether. As with FIG. 4, an additional coolant may be disposed within the housing, covering the circuit board and jacket, or, as with FIG. 7, gaseous coolant (air, typically) can be blown through the enclosure.

In FIG. 8, the end panel 3B may comprises a manifold 41 which includes coolant supply port 11 and return 12 ports (on the revers), inlet and return plenums 42, 43 within the panel, plenum outlet port 44 and return ports 45 configured on the end panel to align with side wall channels, and plenum-to-jacket/cooling plate outlet and return ports 46 and 47 may be connected to the direct-to-chip coolant supply lines 26 and direct-to-chip coolant return lines 27. The endplate comprising a manifold and the circuit board 7 can be provided in separate pieces, and (1) the plenum-to-jacket/cooling plate outlet and return ports 46 and 47 may be connected to the direct-to-chip coolant supply lines 26 and direct-to-chip coolant return lines 27 with fixed connections (not subject to non-destructive disconnection, welded, fused or glued). These components can be connected with easily releasable fittings such as quick disconnect fittings, blind mate quick connectors (with corresponding male and female components in fluid communication with the ports and channels) or leur lock fittings connectable upon installation of the endplate manifold onto the remainder of the housing and (2) plenum outlet and return ports 44 and 45 may be connected to the channels with quick disconnect fittings or blind mate quick connectors (with corresponding male and female components in fluid communication with the ports and channels) or leur lock fittings, upon installation of the endplate manifold onto the remainder of the housing. (These and other readily connectable/dis-connectable connection means may be used.) The endplate comprising a manifold and the circuit board 7 can be provided in a single assembly, in which the manifold can be permanently fixed to the circuit board 7, such that the circuit board and endplate are not independently translatable relative to the housing, and thus the direct-to-chip coolant supply line 26 and direct-to-chip coolant return line 27 can be permanently fixed to the outlet and return ports 46 and 47, allowing insertion and withdrawal of the endplate and circuit board from the housing in a single assembly, without disrupting a seal between the lines and the ports, while fluid-tight connections between the channels and plenum outlet and return ports 44 and 45 can be established with appropriate seals and gaskets, quick disconnect fittings or blind mate quick connectors or leur locks (with corresponding male and female components) in fluid communication with the ports and channels, upon insertion of the circuit board into the housing.

In use, the system can be implemented by providing the enclosure according to any one of the figures (with one or more panels having the coolant channels), locating a circuit board and heat-generating computer components inside the housing, filling the enclosure with a primary coolant liquid, partially (for two-phase immersion cooling) or completely (for single-phase immersion cooling), or a primary coolant gas (air, for example), and connecting the coolant channels within the panels to a source of a secondary coolant, and circulating the secondary coolant through the channels and a heat exchanger. The method may also include, as mentioned above, operating a pump or fan within or without the enclosure to circulate or mix the primary coolant within the enclosure. In this method, heat drawn from the heat generating components into the primary coolant will be transferred to the secondary coolant in the channels, and heat in the secondary channels will be transferred to a third coolant by the external heat exchanger.

The variation of the computer cooling system illustrated above may be implemented with all of the panels, even the end panels, with channels for coolant flow, or they may be implemented with any one or more of the panels with channels, with the remainder being provided without channels. This may be advantageous for retrofit of existing enclosures, which may be provided with improved cooling by replacing only one panel (such as the easily removable top panel) with a panel with cooling channels and replacing the existing endplate with an endplate including the necessary coolant inlet and outlet ports. Even in systems with several panels fitting with coolant channels, the system may be operated with coolant flow through all the panels or any subset of panels, depending on the heat load of the enclosed components.

While the preferred embodiments of the devices and methods have been described in reference to the environment in which they were developed, they are merely illustrative of the principles of the inventions. The elements of the various embodiments may be incorporated into each of the other species to obtain the benefits of those elements in combination with such other species, and the various beneficial features may be employed in embodiments alone or in combination with each other. Other embodiments and configurations may be devised without departing from the spirit of the inventions and the scope of the appended claims.

We claim:

1. A computer component cooling system comprising:
a housing (2) for housing computer components, said housing comprising housing panels including a top panel (2T), bottom panel (2B), first side panel (2R) and second side panel (2L), a front end panel (3F) and a back end panel (3B), wherein at least one of housing panels includes a coolant channel (any one of 4L, 4R, 4C, 5S, or 5R) disposed between an exterior wall of the panel and an interior wall of the panel; wherein the housing includes a gas intake aperture (34) and a gas outlet aperture (34 35);
a fan (24) disposed in fluid communication with the apertures (34, 35) and an interior space of the housing, said fan (24) configured to draw cooling gas into the housing through the gas intake aperture (34) and exhaust gas through the gas outlet aperture (35); and
a heat exchanger (10) in fluid communication with the coolant channels, through a supply line (13) and return line (14), establishing a coolant loop (4 or 5, 13, 14) for flow of a secondary coolant through the at least one of housing panels; and
a pump (15) operable to pump the secondary coolant through the coolant loop (4 or 5, 13, 14) and heat exchanger.

2. The computer component cooling system of claim 1, wherein:
coolant gas passing through the housing (2) acts as a primary coolant to cool computer components within the housing;
flow of secondary coolant through the coolant channels cools the coolant gas.

3. The system of claim 1, further comprising:
cooling fins or pins 6 disposed on an interior surface of at least one of the panels.

4. The system of claim 1, wherein:
the outer surface of at least one, and preferably all, of the panels is devoid of cooling fins.

5. The system of claim 1, wherein:
cooling fins or pins 6 disposed on an interior surface of at least one of the panels; and
the outer surface of at least one, and preferably all, of the panels is devoid of cooling fins.

6. The system of claim 2, further comprising:
a computerized control system and a sensor operable to sense temperature of cooling gas passing through and exiting the housing, said control system operable to receive signals from the sensor indicative of the temperature of the cooling gas passing through and exiting the housing and control the pump and/or the fan to balance flow of cooling gas through the housing and flow of coolant fluid through the channel of the panel to cool the cooling gas passing through the housing.

7. A method of cooling computer components within a housing, said method comprising:
providing the computer component cooling system of claim 1, and disposing heat generating computer components within the housing;
operating the fan to force cooling gas through the housing to cool the computer components within the housing; while operating the pump to force a coolant fluid through the coolant a channel of one or more of the panels; and
controlling the fan and pump to balance flow of cooling gas through the housing and flow of coolant fluid through the channel of the panel to cool the cooling gas exhausted from the housing.

8. A computer component cooling system comprising:
a housing (2) for housing computer components including a heat-generating computer component (9), said housing comprising housing panels including a top panel (2T), bottom panel (2B), first side panel (2R) and second side panel (2L), a front end panel (3F) and a back end panel (3B);
a cooling module (25) disposed in thermal contact with the heat-generating computer component (9);
an endplate manifold (41) integrated with one of the front or back end panels (3) of the housing, the endplate manifold comprising:
a coolant supply port (11) and a coolant return port (12) configured for connection to an external heat exchanger (10);
a supply plenum (42) and a return plenum (43) disposed within the endplate manifold (41); and
a direct-to-chip coolant supply line (26) extending from the supply plenum (42) to the cooling module (25);
a direct-to-chip coolant return line (27 extending from the cooling module (25) to the return plenum (43); wherein
the coolant supply port (11), supply plenum (42), direct-to-chip coolant supply line (26), cooling module (25), direct-to-chip coolant return line (27), return plenum (43), and coolant return port (12) establish a coolant flow path between the external heat exchanger (10) and the cooling module (25).

9. The computer component cooling system of claim 8, wherein:
the endplate manifold (41) is fixed relative to the circuit board (7) such that the circuit board and endplate manifold are insertable into and removable from the housing as a single assembly while maintaining fluid-tight connections between (A) the direct-to-chip coolant supply line (46) and the direct-to-chip coolant supply plenum (42 and (B) the direct-to-chip coolant return line (47) and the coolant return plenum (43).

10. The computer component cooling system of claim 8, wherein:
wherein at least one of the top panel (2T), bottom panel (2B), first side panel (2R) and second side panel (2L), includes a coolant channel (any one of 4L, 4R, 4C, 5S, or 5R) disposed between an exterior wall (20) of the panel and an interior wall of the panel; and
the manifold (41) comprises a panel supply port (44) and a panel return port (45), said panel supply port (44) positioned on the manifold such that, when the first end panel is fixed to the housing (2), the panel supply port (44) is placed in fluid communication with a first channel of a panel, said panel return port (45) positioned on the manifold (41) such that, when the first end panel (3B) is fixed to the housing (2), the panel return port (45) is placed in fluid communication with a second channel of a panel.

11. The computer component cooling system thing of claim 9, wherein:
the first channel of a panel and the second channel are both disposed within the same panel.

12. The computer component cooling system thing of claim 8, further comprising:
cooperating components of releasable fittings disposed at the plenum outlet port (44) and return ports (45) configured on the end panel to align with channels in a panel.

13. The computer component cooling system thing of claim 12, wherein the releasable fittings comprise quick disconnect fittings, blind mate quick connectors or leur lock fittings.

14. The computer component cooling system thing of claim 8, further comprising:
cooperating components of releasable fittings disposed at the plenum outlet port (46) and return ports (47) configured on the end panel to align with direct-to-chip coolant supply line (26) and direct-to-chip coolant return line (27).

15. The computer component cooling system thing of claim 14, wherein the releasable fittings comprise quick disconnect fittings, blind mate quick connectors or leur lock fittings.
